(19) United States
(12) Patent Application Publication
(10) Pub. No.: US 2026/0247784 A1
(43) Pub. Date: Aug. 20, 2026

(54) PEROVSKITE SOLAR CELL AND METHOD FOR MANUFACTURING SAME

(71) Applicant: JUSUNG ENGINEERING CO., LTD., Gwangju-si, Gyeonggi-do (KR)

(72) Inventors: Jae Ho KIM, Yongin-si, Gyeonggi-do (KR); Chul Joo HWANG, Yongin-si, Gyeonggi-do (KR)

(21) Appl. No.: 18/870,270

(22) PCT Filed: Jun. 19, 2023
(86) PCT No.: PCT/KR2023/008472

§ 371 Date: Nov. 27, 2024

(30) Foreign Application Priority Data
Jun. 30, 2022 (KR) 10-2022-0080777
Jan. 11, 2023 (KR) 10-2023-0003964
Jun. 12, 2023 (KR) 10-2023-0074825

(51) Int. Cl. H10K 30/87; H10K 30/57; H10K 30/85; H10K 30/88

(52) U.S. Cl. CPC H10K 30/87; H10K 30/57; H10K 30/85; H10K 30/88

(57) ABSTRACT

The present inventive concept provides a solar cell and a method for manufacturing same, the solar cell comprising: a light absorbing layer comprising a perovskite compound; and an electron transporting layer on one surface of the light absorbing layer, wherein the electron transporting layer consists of a first electron transporting layer on the one surface of the light absorbing layer, and a second electron transporting layer on the first electron transporting layer, the first electron transporting layer consists of an inorganic metal nitride, and the second electron transporting layer consists of an inorganic metal nitride oxide.

### TECHNICAL FIELD

The present inventive concept relates to a perovskite solar cell and method of manufacturing the same, and more particularly, to an electron transport layer of the perovskite solar cell.

### BACKGROUND ART

Perovskite solar cells include a light absorption layer containing a perovskite compound, an electron transport layer on one side of the light absorption layer, and a hole transport layer on the other side of the light absorption layer.

Conventionally, a structure in which an organic material layer of C60 and a metal oxide layer are sequentially stacked was used as the electron transport layer. However, in the case of such a structure, there is a problem that the metal oxide layer passes through the organic layer of C60 and the perovskite compound constituting the light absorption layer is oxidized, thereby reducing the efficiency of the solar cell.

### DISCLOSURE

### Technical Problem

The present inventive concept is devised to solve the above-described problem and is for providing a solar cell having an electron transport layer capable of preventing oxidation of a perovskite compound constituting the light absorption layer and a method for manufacturing the same.

### Technical Solution

To accomplish the above-described objects, an embodiment of the present inventive concept provides a solar cell comprising a light absorption layer including a perovskite compound; and an electron transport layer provided on a first surface of the light absorption layer, wherein the electron transport layer includes a first electron transport layer provided on the first surface of the light absorption layer and a second electron transport layer provided on the first electron transport layer, and wherein the first electron transport layer includes an inorganic metal nitride and the second electron transport layer includes an inorganic metal nitride oxide, or the first electron transport layer includes inorganic metal sulfide and the second electron transport layer includes inorganic metal sulfide oxide.

Another embodiment of the present inventive concept provides a solar cell comprising a light absorption layer including a perovskite compound; and an electron transport layer provided on a first surface of the light absorption layer, wherein the electron transport layer includes a first electron transport layer provided on the first surface of the light absorption layer and a third electron transport layer provided on the first electron transport layer, and wherein the first electron transport layer includes an inorganic metal nitride or inorganic metal sulfide, and the third electron transport layer includes an inorganic metal oxide.

Another embodiment of the present inventive concept provides a method of manufacturing a solar cell comprising forming a light absorption layer including a perovskite compound; and forming an electron transport layer on a first surface of the light absorption layer, wherein the forming the electron transport layer comprises: forming an electron transport precursor layer including inorganic metal nitride or inorganic metal sulfide, and performing oxygen plasma treatment on the electron transport precursor layer to form a first electron transport layer including the inorganic metal nitride or the inorganic metal sulfide and a second electron transport layer including an inorganic metal nitride oxide or the inorganic metal sulfide oxide.

Another embodiment of the present inventive concept provides a method of manufacturing a solar cell comprising forming a light absorption layer including a perovskite compound; and forming an electron transport layer on a first surface of the light absorption layer, wherein the forming the electron transport layer comprises: forming an electron transport precursor layer including inorganic metal nitride or inorganic metal sulfide, and performing oxygen plasma treatment on the electron transport precursor layer to form a first electron transport layer including the inorganic metal nitride or the inorganic metal sulfide and a third electron transport layer including an inorganic metal oxide.

### Advantageous Effect

According to the present inventive concept, the following effects may be realized.

According to an embodiment of the present inventive concept, an electron transport precursor layer consisting of inorganic nitrides, particularly inorganic nitrides that do not contain oxygen, specifically SnN or ZnN, is formed on the light absorption layer, alternatively, an electron transport precursor layer consisting of an inorganic sulfide, particularly an inorganic sulfide that does not contain oxygen, specifically SnS, SnS₂ or ZnS is formed on the light absorption layer. Accordingly, since inorganic nitrides such as SnN or ZnN or inorganic sulfides such as SnS, SnS₂, or ZnS do not contain oxygen, the perovskite compound constituting the light absorption layer may be prevented from oxidizing during the process of forming the electron transport precursor layer.

According to an embodiment of the present inventive concept, the first electron transport layer including the inorganic nitride or the inorganic sulfide may function as a damage prevention film or a barrier film for an underlayer thereof. In addition, the second electron transport layer including inorganic metal nitric oxide or inorganic metal sulfide oxide may function as a damage prevention film or barrier film for an underlayer thereof.

According to an embodiment of the present inventive concept, a first electron transport layer consisting of inorganic nitrides, particularly inorganic nitrides that do not contain oxygen, specifically SnN or ZnN, is formed on the light absorption layer, alternatively, a first electron transport layer consisting of an inorganic sulfide, particularly an inorganic sulfide that does not contain oxygen, specifically SnS, SnS₂ or ZnS is formed on the light absorption layer. Accordingly, since inorganic nitrides such as SnN or ZnN or inorganic sulfides such as SnS, SnS₂, or ZnS do not contain oxygen, the perovskite compound constituting the light absorption layer provided under the first electron transport layer may be prevented from oxidizing.

According to an embodiment of the present inventive concept, the thickness of the second electron transport layer is thicker than the thickness of the first electron transport layer, thereby improving electrical conductivity characteristics.

### DESCRIPTION OF DRAWINGS

FIGS. 1A to 1D are process diagrams of manufacturing a solar cell according to an embodiment of the present inventive concept.

FIGS. 2A to 2E are process diagrams of manufacturing a solar cell according to another embodiment of the present inventive concept.

FIGS. 3A to 3G are process diagrams of manufacturing a solar cell according to another embodiment of the present inventive concept.

FIGS. 4A to 4H are process diagrams of manufacturing a solar cell according to another embodiment of the present inventive concept.

FIGS. 5A to 5D are process diagrams of manufacturing a solar cell in accordance with another embodiment of this inventive concept.

### MODE FOR INVENTIVE CONCEPT

Advantages and features of the present inventive concept, and implementation methods thereof will be clarified through following embodiments described with reference to the accompanying drawings. The present inventive concept may, however, be embodied in different forms and should not be construed as limited to the embodiments set forth herein. Rather, these embodiments are provided so that this inventive concept will be thorough and complete, and will fully convey the scope of the present inventive concept to those skilled in the art. Furthermore, the present inventive concept is only defined by scopes of claims.

A shape, a size, a ratio, an angle, and a number disclosed in the drawings for describing embodiments of the present inventive concept are merely an example, and thus, the present inventive concept is not limited to the illustrated details. Like reference numerals refer to like elements throughout. In the following description, when the detailed description of the relevant known technology is determined to unnecessarily obscure the important point of the present inventive concept, the detailed description will be omitted. In a case where ‘comprise’, ‘have’, and ‘include’ described in the present specification are used, another part may be added unless ‘only~’ is used. The terms of a singular form may include plural forms unless referred to the contrary.

In construing an element, the element is construed as including an error range although there is no explicit description.

In describing a position relationship, for example, when a position relation between two parts is described as ‘on~’, ‘over~’, ‘under~’, and ‘next~’, one or more other parts may be disposed between the two parts unless ‘just’ or ‘direct’ is used.

In describing a time relationship, for example, when the temporal order is described as ‘after~’, ‘subsequent~’, ‘next~’, and ‘before~’, a case which is not continuous may be included unless ‘just’ or ‘direct’ is used.

It will be understood that, although the terms “first”, “second”, etc. may be used herein to describe various elements, these elements should not be limited by these terms. These terms are only used to distinguish one element from another. For example, a first element could be termed a second element, and, similarly, a second element could be termed a first element, without departing from the scope of the present inventive concept.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

Features of various embodiments of the present inventive concept may be partially or overall coupled to or combined with each other, and may be variously inter-operated with each other and driven technically as those skilled in the art can sufficiently understand. The embodiments of the present inventive concept may be carried out independently from each other, or may be carried out together in co-dependent relationship.

Hereinafter, preferable embodiments of the present inventive concept will be described in detail with reference to the accompanying drawings.

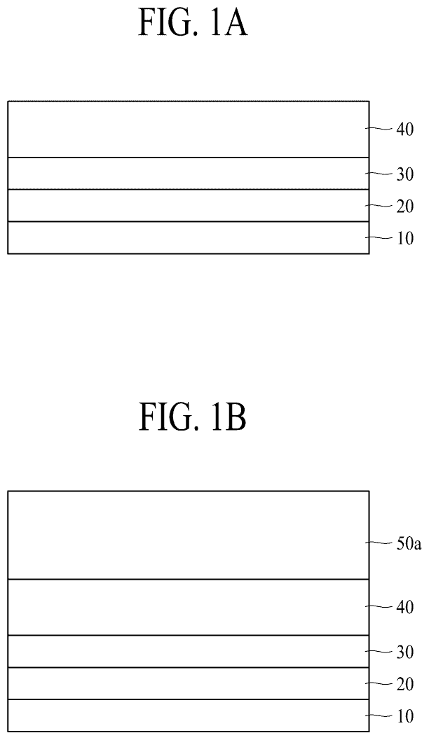

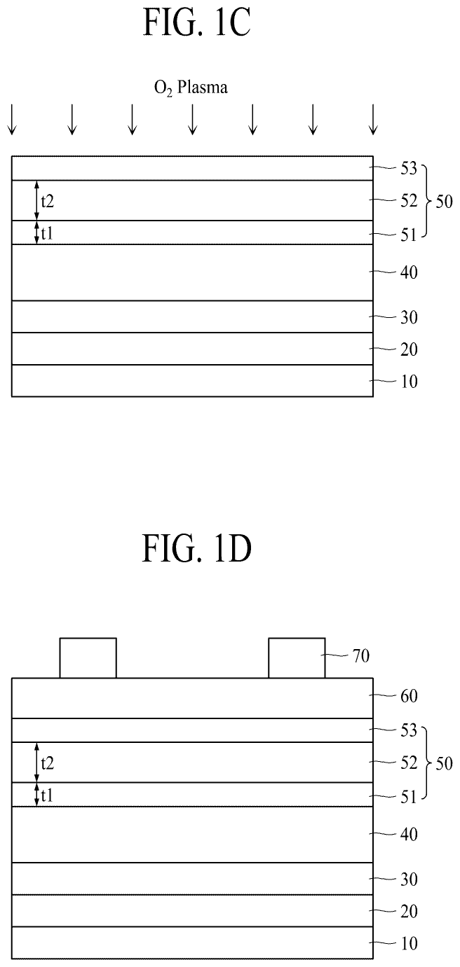

FIGS. 1A to 1D are process diagrams of manufacturing a solar cell according to an embodiment of the present inventive concept.

First, as shown in FIG. 1A, a first electrode 20 is formed on a substrate 10, a hole transport layer 30 is formed on the first electrode 20, and a light absorption layer 40 is formed on the hole transport layer 30.

The substrate 10 may be made of a material known in the art such as glass or plastic.

The first electrode 20 may be made of a conductive oxide such as ITO, but is not limited thereto. The first electrode 20 may be formed by a deposition process such as atomic layer deposition (ALD).

The hole transport layer may include various p-type organic materials known to those skilled in the art such as Spiro-MeO-TAD, Spiro-TTB, polyaniline, polyphenol, poly (3,4-ethylenedioxythiophene)-poly (styrenesulfonate) (PEDOT-PSS), poly[bis(4-phenyl) (2,4,6-trimethylphenyl) amine] (PTAA), and poly(3-hexylthiophene-2,5-diyl) (P3HT), or may include various P-type metal oxides known to those skilled in the art such as Ni oxide, Mo oxide, V oxide, W oxide, or Cu oxide, or may include various P-type organic or inorganic materials known to those skilled in the art. The hole transport layer 30 can be formed by a deposition process such as CVD (Chemical Vapor Deposition) or ALD (Atomic Layer Deposition).

The light absorption layer 40 is made of a perovskite compound.

The perovskite compound may be obtained by depositing ABX₃ compounds by reacting at least one compound selected from amine-based compounds and amidine-based compounds, organic metal compound containing a divalent positive ion, and at least one hydrogen halide through chemical vapor deposition (CVD) or Atomic Layer Deposition (ALD).

In the ABX₃, the A may consist of the monovalent organic positive ion of the amine-based compound, the monovalent organic positive ion of the amidine-based compound, or the monovalent organic positive ion of the amine-based compound and the monovalent organic positive ion of the amidine-based compound. The A may have a structure where the monovalent organic positive ion of the amine-based compound is included therein at an x ratio and the monovalent organic positive ion of the amidine-based compound is included therein at a y ratio. In this case, each of x and y is greater than 0, and x+y=1.

In the ABX₃, the B consists of the divalent positive ion of the organic metal compound.

In the ABX₃, the X consists of one or more halogen compounds.

The amine-based compound may be selected from the group consisting of methylamine, ethylamine, and phenethylamine.

The amidine-based compound may consist of formamidine.

The organic metal compound including the divalent positive ion may include metal selected from the group consisting of lead (Pb), tin (Sn), germanium (Ge), antimony (Sb), bismuth (Bi), and barium (Ba).

In detail, the organic metal compound including the divalent positive ion may include a compound represented by the following Formula 1:

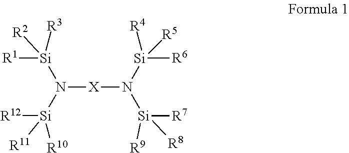

(In the Formula 1, each of R¹ to R¹² consists of hydrogen or an alkyl group independently, and X is selected from the group consisting of Pb, Sn, Ge, Sb, Bi, and Ba)

Alternatively, the organic metal compound including the divalent positive ion may be selected from among the group consisting of Pb(CH₃)₄, Pb(C₂H₅)₄, Pb(SCN)₂, (C₂H₅)₃PbOCH₂C(CH₃)₃, Pb(C₁₁H₁₉O₂)₂, Pb((CH₃)₃C—COCHCO—C(CH₃)₃)₂, Pb((C₆H₅)₂PCH₂P (C₆H₅)₂)₂, Pb(N (CH₃)₂C(CH₃)₂OH)₂, and C₁₂H₂₈N₂O₂Pb.

A light absorption rate, an optical band gap, carrier mobility, and material stability of a finally obtained perovskite compound may be adjusted based on the kind of the organic metal compound including the divalent positive ion.

The hydrogen halide may be selected from the group consisting of HI, HBr, HF, and HCl. The optical band gap of the finally obtained perovskite compound may be adjusted based on the kind of the hydrogen halide.

The amine-based compound, the amidine-based compound, the organic metal compound including the divalent positive ion, and the hydrogen halide include a material which is vaporized at a temperature within a range of a room temperature to 200° C., and preferably, include a material which is vaporized at a temperature within a range of 50° C. to 150° C. Therefore, in a process of manufacturing a compound of the ABX₃, a chemical vapor deposition (CVD) process or an atomic layer deposition (ALD) process may be performed at a temperature of 200° C. or less, preferably, a temperature of 150° C. or less, and thus, an organic material of a finally obtained compound of ABX₃ may be prevented from being decomposed in performing the CVD process or the ALD process. Also, plasma may be applied in performing the CVD process or the ALD process.

According to another embodiment of this inventive concept, the perovskite compound may be obtained by depositing CABX₃ compounds by reacting at least one compound selected from amine-based compounds and amidine-based compounds, at least one alkali metal-based compound, organic metal compound containing a divalent positive ion, and at least one hydrogen halide through chemical vapor deposition (CVD) or Atomic Layer Deposition (ALD).

In the CABX₃, the A may consist of the monovalent organic positive ion of the amine-based compound, the monovalent organic positive ion of the amidine-based compound, or the monovalent organic positive ion of the amine-based compound and the monovalent organic positive ion of the amidine-based compound.

In the CABX₃, the C may consist of the at least one alkali metal-based compound.

The CA may have a structure where the monovalent organic positive ion of the amine-based compound is included therein at an x ratio, the monovalent organic positive ion of the amidine-based compound is included therein at a y ratio, and a monovalent position ion of an alkali metal is included therein at a z ratio. In this case, each of x, y, and z is greater than 0, and x+y+z=1.

In the CABX₃, the B consists of the divalent positive ion, and the X consists of one or more halogen compounds.

The amine-based compound, the amidine-based compound, the organic metal compound including the divalent positive ion, and the hydrogen halide are as described above, and thus, their repeated descriptions are omitted.

The alkali metal-based compound may include a compound represented by the following Formula 2:

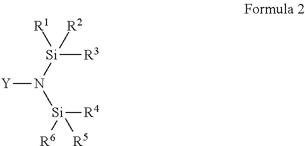

(In the Formula 2, each of R¹ to R⁶ consists of hydrogen or an alkyl group independently, and the Y is an alkali metal)

As described above, according to another embodiment of the present inventive concept, at least one alkali metal-based compound may be added to a reactant, and thus, the instability of a monovalent organic positive ion vulnerable to water, heat, and plasma may be complemented.

Next, as shown in FIG. 1B, an electron transport precursor layer 50a is formed on the light absorption layer 40.

The electron transport precursor layer 50a may be formed of an inorganic nitride, particularly an inorganic nitride that does not contain oxygen. Specifically, the electron transport precursor layer 50a may be formed of SnN or ZnN.

The electron transport precursor layer 50a may be formed of an inorganic sulfide, particularly an inorganic sulfide that does not contain oxygen. Specifically, the electron transport precursor layer 50a may be formed of SnS, SnS₂, or ZnS.

The inorganic nitride such as SnN or ZnN may be formed by a deposition process such as CVD or ALD. Since the inorganic nitride such as SnN or ZnN does not contain oxygen, oxidation of the perovskite compound constituting the light absorption layer 40 may be prevented during the process of forming the electron transport precursor layer 50a.

The inorganic sulfide such as SnS, SnS₂, or ZnS may be formed by a deposition process such as CVD or ALD. Since the inorganic sulfide such as SnS, SnS₂, or ZnS does not contain oxygen, oxidation of the perovskite compound constituting the light absorption layer 40 may be prevented during the process of forming the electron transport precursor layer 50a.

Next, as shown in FIG. 1C, an oxygen plasma treatment is performed on the electron transport precursor layer 50a.

Then, oxygen can be injected into inorganic metal nitrides such as SnN or ZnN, and the electron transport precursor layer 50a can be transformed into an electron transport layer 50 including the first electron transport layer 51, the second electron transport layer 52, and the third electron transport layer 53.

Alternatively, oxygen may be injected into inorganic metal sulfides such as SnS, SnS₂, or ZnS, and the electron transport precursor layer 50a may be transformed into an electron transport layer 50 including the first electron transport layer 51, the second electron transport layer 52, and the third electron transport layer 53.

The first electron transport layer 51 is a layer in contact with the light absorption layer 40, and is made of the same material as inorganic metal nitride or inorganic metal sulfide that constitutes the electron transport precursor layer 50a because oxygen is not introduced thereto. Therefore, the first electron transport layer 51 may consist of an inorganic metal nitride that does not contain oxygen, specifically SnN or ZnN, or an inorganic metal sulfide that does not contain oxygen, specifically SnS, SnS₂ or ZnS.

Since the inorganic nitride such as SnN or ZnN and the inorganic sulfide such as SnS, SnS₂, or ZnS do not contain oxygen, oxidation of the perovskite compound constituting the light absorption layer provided under the first electron transport layer 51 may be prevented. Therefore, the first electron transport layer 51 including the inorganic nitride or the inorganic sulfide may function as a damage prevention film or a barrier film of an underlayer thereof.

The second electron transport layer 52 is a layer formed on the first electron transport layer 51 and in contact with the first electron transport layer 51, and oxygen is partially injected into the inorganic metal nitride or inorganic metal sulfide that constitutes the electron transport precursor layer 50a. Therefore, the second electron transport layer 52 may be made of inorganic metal nitride oxide, specifically SnON or ZnON, or inorganic metal sulfide oxide, specifically SnOS or ZnOS. The second electron transport layer 52 containing the inorganic metal nitride oxide or the inorganic metal sulfide oxide can function as a damage prevention layer or a barrier layer of an underlayer thereof.

The third electron transport layer 53 is a layer formed on the second electron transport layer 52 and in contact with the second electron transport layer 52, and oxygen is injected into the inorganic metal nitride constituting the electron transport precursor layer 50a to replace nitrogen with oxygen, or oxygen is injected into the inorganic metal sulfide constituting the electron transport precursor layer 50a to replace sulfur with oxygen. Accordingly, the third electron transport layer 53 may be formed of an inorganic metal oxide, specifically SnO or ZnO.

Since the first electron transport layer 51 is composed of an inorganic metal nitride or an inorganic metal sulfide that does not contain oxygen, specifically SnN, ZnN, SnS, SnS₂, or ZnS, oxidation of the perovskite compound constituting the light absorption layer 40 provided thereunder may be prevented, but electrical conductivity thereof is not good.

On the other hand, the second electron transport layer 52 is made up of inorganic metal nitride oxide or inorganic metal sulfide oxide, specifically SnON, ZnON, SnOS, or ZnOS, so it has excellent electrical conductivity compared to the first electron transport layer 51. Therefore, in order to improve electrical conductivity characteristics, it is desirable that the thickness t2 of the second electron transport layer 52 is thicker than the thickness t1 of the first electron transport layer 51.

In some cases, the second electron transport layer 52 may not be formed in process 1C. Specifically, by performing oxygen plasma treatment on the electron transport precursor layer 50a, the second electron transport layer 52 may not be formed on the first electron transport layer 51 that is same as the electron transport precursor layer 50a, but the third electron transport layer 53 may be directly formed on the first electron transport layer 51.

For example, a third electron transport layer 53 made of SnO or ZnO may be formed directly on the top of the first electron transport layer 51 containing inorganic metal nitrides such as SnN or ZnN, or a third electron transport layer 53 made of SnO or ZnO may be formed directly on the top of the first electron transport layer 51 containing inorganic metal sulfides such as SnS, SnS₂, or ZnS. In this case, the thickness of the third electron transport layer 53 is thicker than the thickness of the first electron transport layer 51.

Next, as shown in FIG. 1D, a transparent conductive layer 60 is formed on the electron transport layer 50 and a second electrode 70 is formed on the transparent conductive layer 60.

The transparent conductive layer 60 may include a material having electron transport characteristics. The transparent conductive layer 60 may include ITO or IZO, but is not limited thereto. The transparent conductive layer 60 may be formed by a deposition process such as ALD.

The second electrode 70 may be made of a metal material such as Ag. The second electrode 70 may be patterned in a predetermined shape so that sunlight may enter the battery.

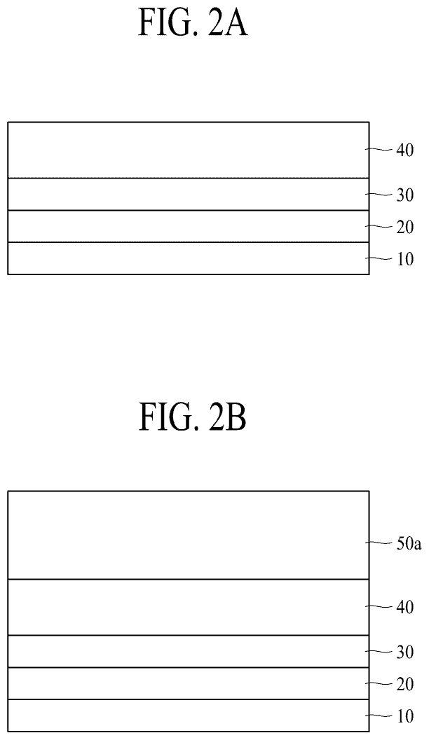

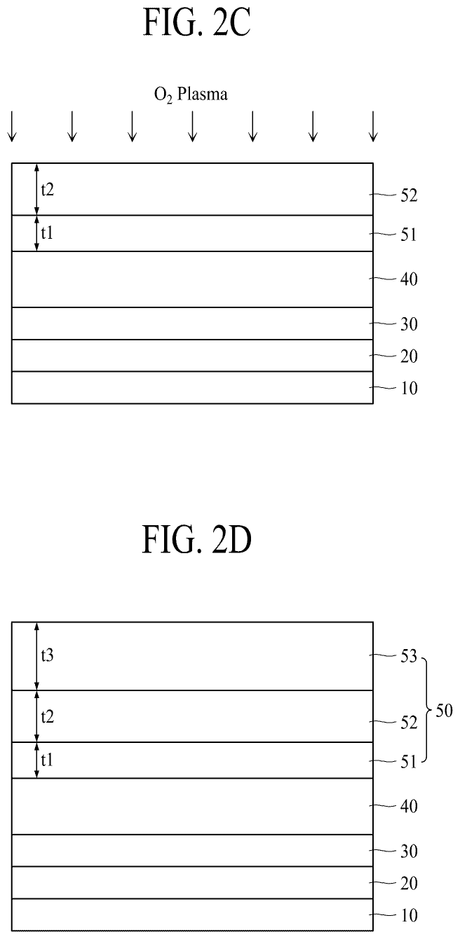

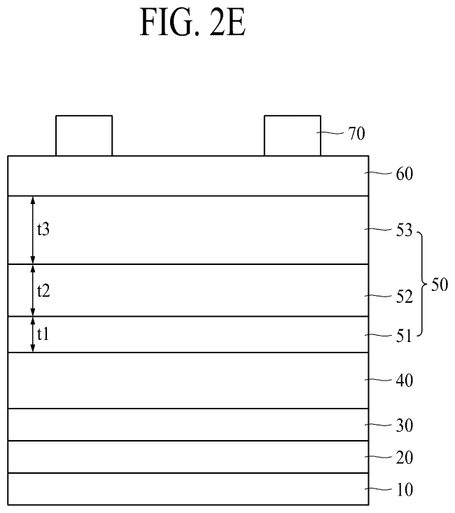

FIGS. 2A to 2E are process diagrams of manufacturing a solar cell according to another embodiment of the present inventive concept.

First, as shown in FIG. 2A, a first electrode 20 is formed on a substrate 10, a hole transport layer 30 is formed on the first electrode 20, and a light absorption layer 40 is formed on the hole transport layer 30.

The specific configurations of the substrate 10, the first electrode 20, the hole transport layer 30, and the light absorption layer 40 are the same as those of the aforementioned embodiment, and thus repeated explanations will be omitted.

Next, as shown in FIG. 2B, an electron transport precursor layer 50a is formed on the light absorption layer 40.

The specific configuration of the substrate 10, the electron transport precursor layer 50a is the same as that of the aforementioned embodiment, and thus repeated explanations will be omitted.

Next, as shown in FIG. 2C, an oxygen plasma treatment is performed on the electron transport precursor layer 50a.

Then, oxygen can be injected into inorganic metal nitrides such as SnN or ZnN, and the electron transport precursor layer 50a can be transformed into the first electron transport layer 51 and the second electron transport layer 52.

Alternatively, oxygen can be injected into inorganic metal sulfides such as SnS, SnS₂, or ZnS, and the electron transport precursor layer 50a can be transformed into the first electron transport layer 51 and the second electron transport layer 52.

The first electron transport layer 51 is a layer in contact with the light absorption layer 40, and is made of the same material as inorganic metal nitride or inorganic metal sulfide that constitutes the electron transport precursor layer 50a because oxygen is not introduced thereto. Therefore, the first electron transport layer 51 may consist of an inorganic metal nitride that does not contain oxygen, specifically SnN or ZnN, or an inorganic metal sulfide that does not contain oxygen, specifically SnS, SnS₂ or ZnS.

The second electron transport layer 52 is a layer formed on the first electron transport layer 51, in which oxygen is partially injected into the inorganic metal nitride or the inorganic metal sulfide constituting the electron transport precursor layer 50a. Therefore, the second electron transport layer 52 may be made of inorganic metal nitride oxide, specifically SnON or ZnON, or inorganic metal sulfide oxide, specifically SnOS or ZnOS.

As in the above-described embodiment, it is preferable that the thickness t2 of the second electron transport layer 52 is thicker than the thickness t1 of the first electron transport layer 51.

In the aforementioned process 1C, the third electron transport layer 53 was additionally formed on the second electron transport layer 52 by oxygen plasma treatment on the electron transport precursor layer 50a. However, depending on the process conditions, even if oxygen is injected into the inorganic metal nitride or the inorganic metal sulfide constituting the electron transport precursor layer 50a, nitrogen or sulfur may not be replaced with oxygen, so the third electron transport layer 53 may not be formed.

Next, as shown in FIG. 2D, a third electron transport layer 53 is formed on the second electron transport layer 52 to form an electron transport layer 50 including the first electron transport layer 51, the second electron transport layer 52, and the third electron transport layer 53.

The third electron transport layer 53 may be formed of an inorganic metal oxide, specifically SnO or ZnO. The third electron transport layer 53 may be formed by a deposition process such as ALD.

At this time, it is desirable that the thickness t3 of the third electron transport layer 53 is thicker than the thickness t1 of the first electron transport layer 51 to improve electrical conductivity characteristics. In addition, the thickness t3 of the third electron transport layer 53 may be thicker than the thickness t2 of the second electron transport layer 52.

In some cases, the third electron transport layer 53 made of an inorganic metal oxide, specifically SnO or ZnO may be formed on the upper surface of the first electron transport layer 51 made of the electron transport precursor layer 50a by omitting the aforementioned process 2C and performing process 2D after the aforementioned process 2B.

Next, as shown in FIG. 2D, a transparent conductive layer 60 is formed on the electron transport layer 50 and a second electrode 70 is formed on the transparent conductive layer 60.

The specific configurations of the transparent conductive layer 60 and the second electrode 70 are the same as those of the aforementioned embodiment, and thus repeated explanations will be omitted.

In the above embodiments, a hole transport layer 30 is formed on the lower surface of the light absorption layer 40, and an electron transport layer 50 is formed on the upper surface of the light absorption layer 40, it is not necessarily limited to this.

A hole transport layer 30 may be formed on the upper surface of the light absorption layer 40, and an electron transport layer 50 may be formed on the lower surface of the light absorption layer 40, and the same is true in the following embodiment.

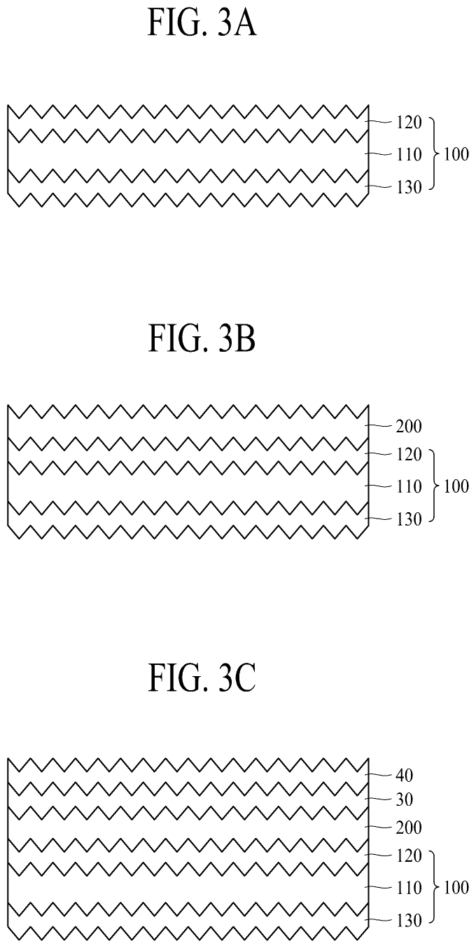

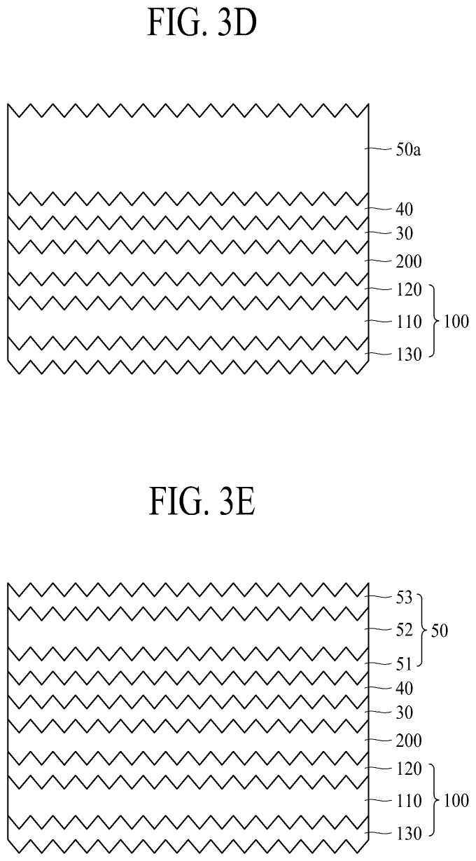

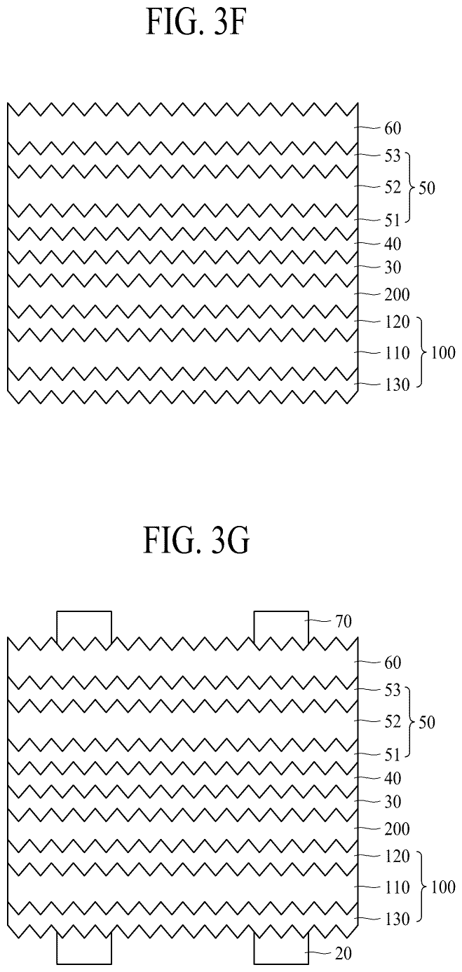

FIGS. 3A to 3G are process diagrams of manufacturing a solar cell according to another embodiment of the present inventive concept, and relate to tandem solar cells of perovskite solar cell and crystalline solar cell.

First, as seen in FIG. 3A, a crystalline solar cell 100 is manufactured.

The crystalline solar cell 100 is manufactured through a process of etching one surface and the other surface of a semiconductor substrate 110 such as a wafer to form a concave-convex structure, doping a certain dopant on the one surface of the semiconductor substrate 110 to form a first semiconductor layer 120, and doping a certain dopant on the other surface of the semiconductor substrate 110 to form a second semiconductor layer 130.

As one surface and the other surface of the semiconductor substrate 110 are formed in the concave-convex structure, the first semiconductor layer 120 and the second semiconductor layer 130 are formed in a shape corresponding to the concave-convex structure.

On the other hand, the drawing shows that both one surface and the other surface of the semiconductor substrate 110 are formed in the concave-convex structure, but it is not necessarily limited to it. One surface of the semiconductor substrate 110 may be formed in the concave-convex structure and the other surface may be formed in a flat structure. Or, the other surface of the semiconductor substrate 110 may be formed in the concave-convex structure and one surface may be formed in a flat structure. In some cases, one surface and the other surface of the semiconductor substrate 110 may be formed in a flat structure.

The semiconductor substrate 110 may be formed of the P-type or N-type wafer, the first semiconductor layer 120 may be doped with a dopant having a polarity different from that of the semiconductor substrate 110, and the second semiconductor layer 130 may be doped with a dopant having the same polarity as that of the semiconductor substrate 110. For example, the semiconductor substrate 110 may be made of a P-type wafer, the first semiconductor layer 120 may be doped with an N-type dopant, and the second semiconductor layer 130 may be doped with a P-type dopant to form a P+ layer.

Next, as seen in FIG. 3B, a buffer layer 200 is formed on the crystalline solar cell 100.

The buffer layer 200 is formed on the first semiconductor layer 120. As the first semiconductor layer 120 is formed in a concave-convex structure, the buffer layer 200 is formed in a shape corresponding to the concave-convex structure.

The buffer layer 200 is provided between the crystalline solar cell 100 and a below-described perovskite solar cell 300, and thus, a solar cell according to an embodiment of the present inventive concept has a structure of a tandem solar cell on the basis of a tunnel junction.

It is preferable that the buffer layer 200 includes a material for enabling light having a long wavelength, passing through the perovskite solar cell 300, to be incident on the crystalline solar cell 100 without being lost. For example, the buffer layer 200 may be formed of a transparent conductive oxide, a carbonaceous conductive material, a metallic material, or a conductive polymer, and in some cases, an n-type or p-type dopant may be doped with the material.

Next, as seen in FIG. 3C, a hole transport layer 30 is formed on the buffer layer 200, and a light absorption layer 40 is formed on the hole transport layer 30.

The specific configurations of the hole transport layer 30 and the light absorption layer 40 are the same as those of the aforementioned embodiment, and thus repeated explanations will be omitted.

Next, as shown in FIG. 3D, an electron transport precursor layer 50a is formed on the light absorption layer 40.

The specific configuration of the electron transport precursor layer 50a is the same as that of the aforementioned embodiment, and thus repeated explanations will be omitted.

Next, as shown in FIG. 3E, oxygen plasma treatment is performed on the electron transport precursor layer 50a.

Then, oxygen is injected into inorganic metal nitrides such as SnN or ZnN or inorganic metal sulfides such as SnS, SnS₂ or ZnS, so that the electron transport precursor layer 50a can be transformed into an electron transport layer 50 including a first electron transport layer 51, a second electron transport layer 52, and a third electron transport layer 53.

The specific configuration of the electron transport layer 50 including the first electron transport layer 51, the second electron transport layer 52, and the third electron transport layer 53 is the same as in FIG. 1C, and thus a repeated description will be omitted. Next, as shown in FIG. 3F, a transparent conductive layer 60 is formed on the electron transport layer 50.

The specific configuration of the transparent conductive layer 60 is the same as that of the aforementioned embodiment, and thus repeated explanations will be omitted.

Next, as seen in FIG. 3G, a first electrode 20 is formed on a bottom surface of the crystalline solar cell 100, and a second electrode 70 is formed on a top surface of the transparent conductive layer 60.

Since the second electrode 70 is formed on an incident surface where sunlight is incident, the second electrode 70 is patterned in a predetermined shape. The first electrode 20 may also be configured to allow reflected light of sunlight to enter the solar cell by forming a pattern in a predetermined shape, but is not limited thereto.

The specific configurations of the first electrode 20 and the second electrode 70 are the same as that of the aforementioned embodiment, and thus repeated explanations will be omitted.

The first electrode 20 and the second electrode 70 may be formed by various conductive materials known in the art through various pattern formation methods.

Although not shown in detail, a passivation layer may be formed on the second electrode 70. In this case, a part of the passivation layer is etched so that the second electrode 70 may be exposed.

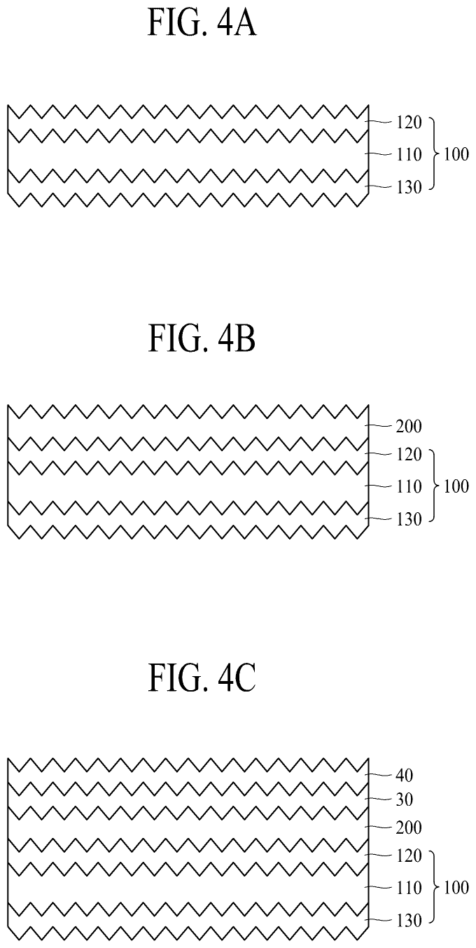

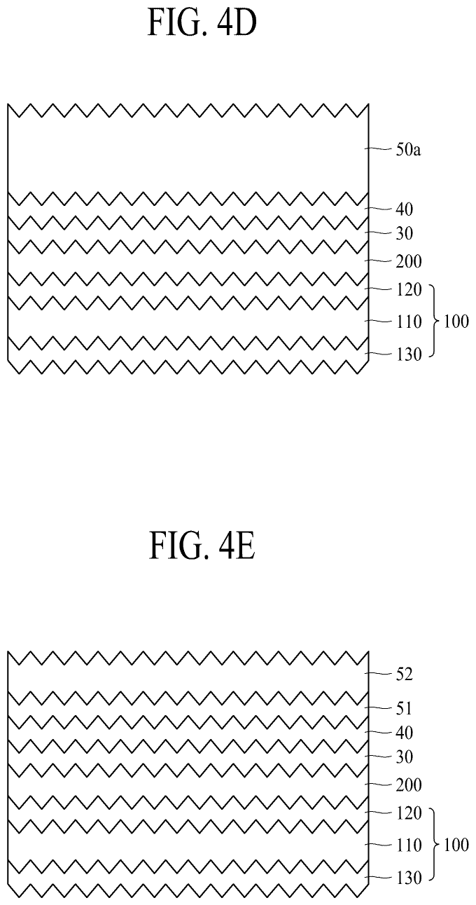

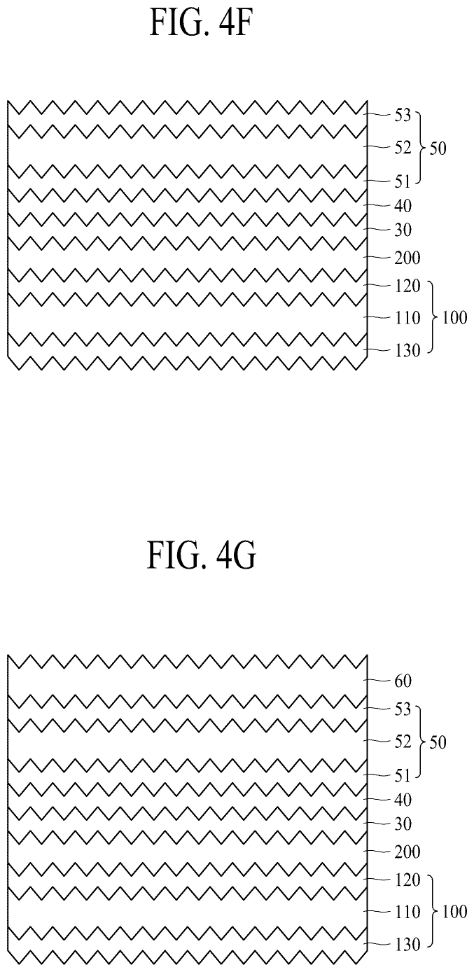

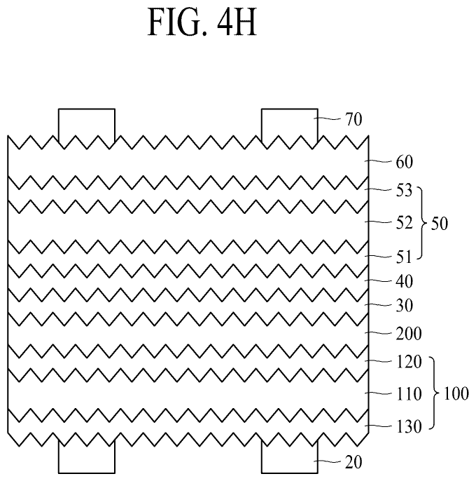

FIGS. 4A to 4H are process diagrams of manufacturing a solar cell according to another embodiment of the present inventive concept, and relate to tandem solar cells of perovskite solar cell and crystalline solar cell.

First, as seen in FIG. 4A, a crystalline solar cell 100 is manufactured.

The crystalline solar cell 100 is manufactured through a process of etching one surface and the other surface of a semiconductor substrate 110 such as a wafer to form a concave-convex structure, doping a certain dopant on the one surface of the semiconductor substrate 110 to form a first semiconductor layer 120, and doping a certain dopant on the other surface of the semiconductor substrate 110 to form a second semiconductor layer 130.

Since the specific configurations of the semiconductor substrate 110, the first semiconductor layer 120, and the second semiconductor layer 130 are the same as those of FIG. 3A, repeated explanations will be omitted.

Next, as seen in FIG. 4B, a buffer layer 200 is formed on the crystalline solar cell 100.

Since the specific configuration of the buffer layer 200 is the same as that of FIG. 3B described above, a repeated description thereof will be omitted.

Next, as seen in FIG. 4C, a hole transport layer 30 is formed on the buffer layer 200, and a light absorption layer 40 is formed on the hole transport layer 30.

Since the specific configurations of the hole transport layer 30 and the light absorption layer 40 are the same as those of FIG. 3C, a repeated description thereof will be omitted.

Next, as shown in FIG. 4D, an electron transport precursor layer 50a is formed on the light absorption layer 40.

Since the specific configuration of the electron transport precursor layer 50a is the same as that of FIG. 3D described above, a repeated description thereof will be omitted. Next, as shown in FIG. 4E, oxygen plasma treatment is performed on the electron transport precursor layer 50a.

Then, oxygen is injected into inorganic metal nitrides such as SnN or ZnN or inorganic metal sulfides such as SnS, SnS₂ or ZnS, so that the electron transport precursor layer 50a can be transformed into a first electron transport layer 51 and a second electron transport layer 52.

Since the specific configurations of the first electron transport layer 51 and the second electron transport layer 52 are the same as that of FIG. 2C described above, a repeated description thereof will be omitted.

Next, as shown in FIG. 4F, a third electron transport layer 53 is formed on the second electron transport layer 52 to form an electron transport layer 50 including the first electron transport layer 51, the second electron transport layer 52, and the third electron transport layer 53.

Since the specific configuration of the third electron transport layer 53 is the same as that of FIG. 2D described above, a repeated description thereof will be omitted.

As in the above embodiment, the electron transport layer 50 including the first electron transport layer 51 and the third electron transport layer 53 provided on the upper surface of the first electron transport layer 51 may be formed by omitting the process 4E and performing process 4F after the process 4D.

Next, as shown in FIG. 4G, a transparent conductive layer 60 is formed on the electron transport layer 50.

Since the specific configuration of the transparent conductive layer 60 is the same as that of FIG. 3F described above, a repeated description thereof will be omitted.

Next, as seen in FIG. 4H, a first electrode 20 is formed on a bottom surface of the crystalline solar cell 100, and a second electrode 70 is formed on a top surface of the transparent conductive layer 60.

Since the detailed configurations of the first electrode 20 and the second electrode 70 are the same as those of FIG. 3G described above, a repeated description thereof will be omitted.

Although not shown in detail, a passivation layer may be formed on the second electrode 70. In this case, a part of the passivation layer is etched so that the second electrode 70 may be exposed.

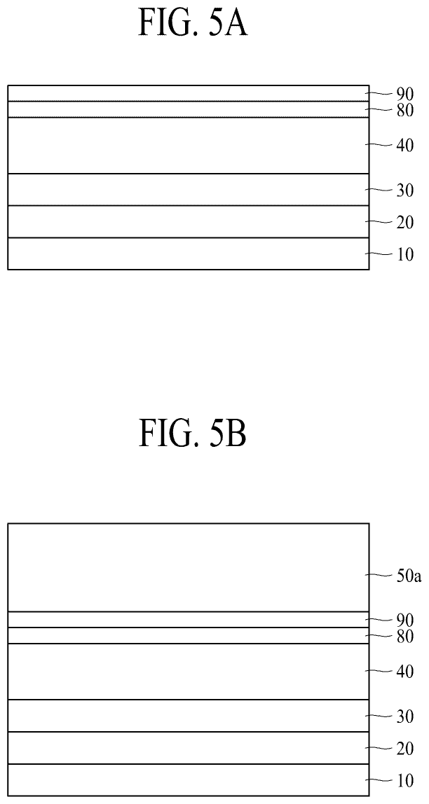

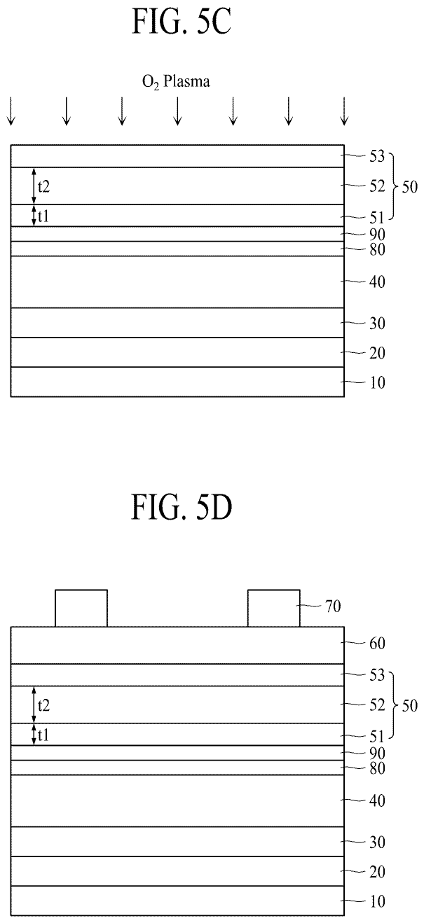

FIGS. 5A to 5D are process diagrams of manufacturing a solar cell in accordance with another embodiment of this inventive concept, which are different from FIGS. 1A to 1D in that they additionally include a process of forming a passivation layer 80 and an organic material layer 90.

First, as shown in FIG. 5A, a first electrode 20 is formed on a substrate 10, a hole transport layer 30 is formed on the first electrode 20, a light absorption layer 40 is formed on the hole transport layer 30, a passivation layer 80 is formed on the light absorption layer 40, and an organic material layer 90 is formed on the passivation layer 80.

The specific configurations of the substrate 10, the first electrode 20, the hole transport layer 30, and the light absorption layer 40 are the same as those of the aforementioned embodiment, and thus repeated explanations will be omitted.

The passivation layer 80 may be formed of an inorganic insulating layer, for example, an inorganic insulating layer that does not contain oxygen such as silicon nitride.

The organic material layer 90 may be formed of fullerene or a fullerene derivative. For example, the organic material layer 90 may be formed of C60 or PCBM ([6,6]-phenyl-C61-butyricacidmethylester).

Next, as shown in FIG. 5B, an electron transport precursor layer 50a is formed on the light absorption layer 40.

Since the specific configuration of the electron transport precursor layer 50a is the same as that of FIG. 1B described above, a repeated description thereof will be omitted. Next, as shown in FIG. 5C, an oxygen plasma treatment is performed on the electron transport precursor layer 50a.

Then, oxygen can be injected into inorganic metal nitrides such as SnN or ZnN, and the electron transport precursor layer 50a can be transformed into an electron transport layer 50 including the first electron transport layer 51, the second electron transport layer 52, and the third electron transport layer 53.

Alternatively, oxygen can be injected into inorganic metal sulfides such as SnS, SnS₂, or ZnS, and the electron transport precursor layer 50a can be transformed into an electron transport layer 50 including the first electron transport layer 51, the second electron transport layer 52, and the third electron transport layer 53.

The specific configurations of the first electron transport layer 51, the second electron transport layer 52, and the third electron transport layer 53 are the same as those of FIG. 1C, and thus a repeated description thereof will be omitted.

In this case, the first electron transport layer 51 and the second electron transport layer 52 may function as a damage prevention film or barrier film that prevents damage to the passivation layer 80 and the organic material layer 90.

Next, as shown in FIG. 5D, a transparent conductive layer 60 is formed on the electron transport layer 50 and a second electrode 70 is formed on the transparent conductive layer 60.

Since specific configurations of the transparent conductive layer 60 and the second electrode 70 are the same as those of FIG. 1D described above, a repeated description thereof will be omitted.

Although not specifically illustrated, the above-described embodiment in accordance with FIGS. 2A to 2E may also additionally include a process of forming the passivation layer 80 and the organic material layer 90. In other words, the passivation layer 80 and the organic material layer 90 may be serially formed on the light absorption layer 40 in the aforementioned FIG. 2A process, and then the electron transport precursor layer 50a may be formed on the organic material layer 90 in the FIG. 2B process.

In addition, the process of forming the passivation layer 80 and the organic material layer 90 may be additionally included in the embodiment according to FIGS. 3A to 3G described above. In other words, the passivation layer 80 and the organic material layer 90 may be serially formed on the light absorption layer 40 in the aforementioned FIG. 3C process, and then the electron transport precursor layer 50a may be formed on the organic material layer 90 in the FIG. 3D process.

In addition, the process of forming the passivation layer 80 and the organic material layer 90 may be additionally included in the embodiment according to FIGS. 4A to 4H described above. In other words, the passivation layer 80 and the organic material layer 90 may be serially formed on the light absorption layer 40 in the aforementioned FIG. 4C process, and then the electron transport precursor layer 50a may be formed on the organic material layer 90 in the FIG. 4D process.

Hereinabove, the embodiments of the present inventive concept have been described in more detail with reference to the accompanying drawings, but the present inventive concept is not limited to the embodiments and may be variously modified within a range which does not depart from the technical spirit of the present inventive concept. Therefore, it should be understood that the embodiments described above are exemplary from every aspect and are not restrictive. It should be construed that the scope of the present inventive concept is defined by the below-described claims instead of the detailed description, and the meanings and scope of the claims and all variations or modified forms inferred from their equivalent concepts are included in the scope of the present inventive concept.

1. A solar cell comprising:
a light absorption layer including a perovskite compound; and
an electron transport layer provided on a first surface of the light absorption layer,
wherein the electron transport layer includes a first electron transport layer provided on the first surface of the light absorption layer and a second electron transport layer provided on the first electron transport layer, and
wherein the first electron transport layer includes an inorganic metal nitride and the second electron transport layer includes an inorganic metal nitride oxide, or the first electron transport layer includes inorganic metal sulfide and the second electron transport layer includes inorganic metal sulfide oxide.

2. The solar cell of claim 1, wherein the first electron transport layer includes SnN and the second electron transport layer includes SnON, or,
the first electron transport layer includes ZnN and the second electron transport layer includes ZnON, or,
the first electron transport layer includes SnS or SnS₂ and the second electron transport layer includes SnOS, or
the first electron transport layer includes ZnS and the second electron transport layer includes ZnOS.

3. The solar cell of claim 1, further comprising a passivation layer between the light absorption layer and the electron transport layer.

4. The solar cell of claim 3, further comprising an organic material layer between the passivation layer and the electron transport layer.

5. The solar cell of claim 1, wherein a thickness of the second electron transport layer is thicker than a thickness of the first electron transport layer.

6. The solar cell of claim 1, further comprising a third electron transport layer on the second electron transport layer, wherein the third electron transport layer comprises an inorganic metal oxide.

7. The solar cell of claim 6, wherein the third electron transport layer comprises SnO or ZnO.

8. A solar cell comprising:
a light absorption layer including a perovskite compound; and
an electron transport layer provided on a first surface of the light absorption layer,
wherein the electron transport layer includes a first electron transport layer provided on the first surface of the light absorption layer and a third electron transport layer provided on the first electron transport layer, and
wherein the first electron transport layer includes an inorganic metal nitride or inorganic metal sulfide, and the third electron transport layer includes an inorganic metal oxide.

9. The solar cell of claim 8, wherein the first electron transport layer includes SnN, SnS or SnS₂, and the third electron transport layer includes SnO, or,
the first electron transport layer includes ZnN or ZnS, and the third electron transport layer includes ZnO.

10. The solar cell of claim 8, wherein a thickness of the third electron transport layer is thicker than a thickness of the first electron transport layer.

11. The solar cell of claim 8, further comprising a passivation layer between the light absorption layer and the electron transport layer and an organic material layer between the passivation layer and the electron transport layer.

12. The solar cell of claim 8, further comprising a transparent conductive layer on the electron transport layer, wherein the transparent conductive layer includes a material having electron transport characteristics.

13. (canceled)

14. (canceled)

15. A method of manufacturing a solar cell comprising:
forming a light absorption layer including a perovskite compound; and
forming an electron transport layer on a first surface of the light absorption layer,
wherein the forming the electron transport layer comprises:
forming an electron transport precursor layer including inorganic metal nitride or inorganic metal sulfide, and
performing oxygen plasma treatment on the electron transport precursor layer to form a first electron transport layer including the inorganic metal nitride or the inorganic metal sulfide.

16. The method of manufacturing a solar cell of claim 15, wherein the electron transport precursor layer and the first electron transport layer include SnN and the second electron transport layer includes SnON, or,
the electron transport precursor layer and the first electron transport layer include ZnN and the second electron transport layer includes ZnON, or,
the electron transport precursor layer and the first electron transport layer include SnS or SnS₂ and the second electron transport layer includes SnOS, or
the electron transport precursor layer and the first electron transport layer include ZnS and the second electron transport layer includes ZnOS.

17. The method of manufacturing a solar cell of claim 15, wherein the forming the electron transport layer further comprises forming a third electron transport layer including an inorganic metal oxide on the second electron transport layer, wherein the third electron transport layer includes SnO or ZnO.

18. The method of manufacturing a solar cell of claim 15, further comprising forming a passivation layer between the light absorption layer and the electron transport layer and forming an organic material layer between the passivation layer and the electron transport layer.

19. The method of manufacturing a solar cell of claim 15, wherein the forming the electron transport layer further comprises forming a third electron transport layer including an inorganic metal oxide on the first electron transport layer.

20. The method of manufacturing a solar cell of claim 19, wherein the first electron transport layer includes SnN, SnS, or SnS₂, and the third electron transport layer includes SnO, or,
the first electron transport layer includes ZnN or ZnS, and the third electron transport layer includes ZnO.

21. (canceled)

22. The method of manufacturing a solar cell of claim 19, further comprising forming a transparent conductive layer on the electron transport layer, wherein the transparent conductive layer includes a material having electron transport characteristics.

23. (canceled)

24. (canceled)

25. The method of manufacturing a solar cell of claim 15, wherein the forming the electron transport layer further comprises forming a second electron transport layer including an inorganic metal nitride oxide or the inorganic metal sulfide oxide on the first electron transport layer.
